(19) United States
(12) Patent Application Publication
(10) Pub. No.: US 2011/0081781 A1
(43) Pub. Date: Apr. 7, 2011

(54) METHOD FOR MANUFACTURING SEMICONDUCTOR

(75) Inventor: Sergey Pidin, Yokohama (JP)

(73) Assignee: FUJITSU SEMICONDUCTOR LIMITED, Yokohama-shi (JP)

(21) Appl. No.: 12/895,207

(22) Filed: Sep. 30, 2010

(30) Foreign Application Priority Data
Oct. 1, 2009 (JP) 2009-229466

(51) Int. Cl. H01L 21/71

(52) U.S. Cl. 438/696; 257/E21.536

(57) ABSTRACT

A method for manufacturing a semiconductor device includes forming a first stress film covering a first transistor arranged in a first region and a second transistor arranged in a second region on a semiconductor substrate; forming an etching stopper film, which possesses etching characteristics different from etching characteristics of the first stress film, on the first stress film; etching the etching stopper film to selectively leave the etching stopper film at a portion covering a sidewall portion of the first stress film in the first region; removing both the etching stopper film and the first stress film in the second region; and forming a second stress film, which possesses etching characteristics different from the etching characteristics of the etching stopper film, on the semiconductor substrate in such a manner as to cover the second transistor, the first stress film.

### CROSS-REFERENCE TO RELATED APPLICATIONS

This application is based upon and claims the benefit of priority of the prior Japanese Patent Application No. 2009-229466, filed on Oct. 1, 2009, the entire contents of which are incorporated herein by reference.

### FIELD

The present invention relates to a method for manufacturing a semiconductor device.

### BACKGROUND

Recently, semiconductor devices including a CMOS circuit having an NMOS transistor and a PMOS transistor have drawn attention.

In such semiconductor devices, a gate wiring is continuously formed in the NMOS transistor region and the PMOS transistor region, for example. A portion of the gate wiring in the NMOS transistor region functions as a gate electrode of the NMOS transistor. A portion of the gate wiring in the PMOS transistor region functions as a gate electrode of the PMOS transistor.

On a semiconductor substrate on which the NMOS transistor and the PMOS transistor are formed, an interlayer insulation film is formed in such a manner as to cover the NMOS transistor and the PMOS transistor. In the interlayer insulation film, a contact hole that reaches the gate wiring is formed and a conductor plug is embedded in the contact hole.

As a method for increasing carrier mobility of the NMOS transistor, a method has been proposed that includes forming a stress film covering the NMOS transistor so that a tensile stress is applied to a channel region of the NMOS transistor. As a method for increasing the carrier mobility of the PMOS transistor, a method has been proposed that includes forming a stress film covering the PMOS transistor so that a compressive stress is applied to a channel region of the PMOS transistor.

Note that, when forming the contact hole that reaches the gate wiring, a favorable contact hole has not been formed in some cases. In this case, reliability of the connection between the conductor plug and the gate wiring may not be sufficiently secured and also a sufficiently high manufacturing yield may not be always obtained.

### SUMMARY

According to one aspect of the invention, a method for manufacturing a semiconductor device includes forming a first stress film covering a first transistor arranged in a first region and a second transistor arranged in a second region on a semiconductor substrate; forming an etching stopper film, which possesses etching characteristics different from etching characteristics of the first stress film, on the first stress film; etching the etching stopper film to selectively leave the etching stopper film at a portion covering a sidewall portion of the first stress film in the first region; removing both the etching stopper film and the first stress film in the second region; forming a second stress film, which possesses etching characteristics different from the etching characteristics of the etching stopper film, on the semiconductor substrate in such a manner as to cover the second transistor, the first stress film, and the etching stopper film; and removing the second stress film in the first region.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are cross sectional views illustrating a semiconductor device according to one embodiment;

FIG. 2 is a plan view illustrating the semiconductor device according to the one embodiment;

FIG. 3 is a graph illustrating simulation results of strain generated in a channel region;

FIGS. 4A and 4B are cross sectional views illustrating a step in a process for manufacturing a semiconductor device according to one embodiment;

FIGS. 5A and 5B are cross sectional views illustrating a step in a process for manufacturing a semiconductor device according to the one embodiment;

FIGS. 6A and 6B are cross sectional views illustrating a step in a process for manufacturing a semiconductor device according to the one embodiment;

FIGS. 7A and 7B are cross sectional views illustrating a step in a process for manufacturing a semiconductor device according to the one embodiment;

FIGS. 8A and 8B are cross sectional views illustrating a step in a process for manufacturing a semiconductor device according to the one embodiment;

FIGS. 9A and 9B are cross sectional views illustrating a step in a process for manufacturing a semiconductor device according to the one embodiment;

FIGS. 10A and 10B are cross sectional views illustrating a step in a process for manufacturing a semiconductor device according to the one embodiment;

FIGS. 11A and 11B are cross sectional views illustrating a step in a process for manufacturing a semiconductor device according to the one embodiment;

FIGS. 12A and 12B are cross sectional views illustrating a step in a process for manufacturing a semiconductor device according to the one embodiment;

FIG. 13 is a cross sectional view illustrating a step in a process for manufacturing a semiconductor device according to the one embodiment;

FIG. 14 is a cross sectional view illustrating a step in a process for manufacturing a semiconductor device according to the one embodiment;

FIGS. 15A and 15B are cross sectional views illustrating a step in a process for manufacturing a semiconductor device according to the one embodiment;

FIGS. 16A to 16G are cross sectional views illustrating steps in an exemplary process for forming a contact hole in a gate wiring of a CMOS circuit; and

FIGS. 17A to 17G are cross sectional views illustrating steps in an exemplary process for forming a contact hole in a gate wiring of a CMOS circuit.

### DETAILED DESCRIPTION OF THE EMBODIMENTS

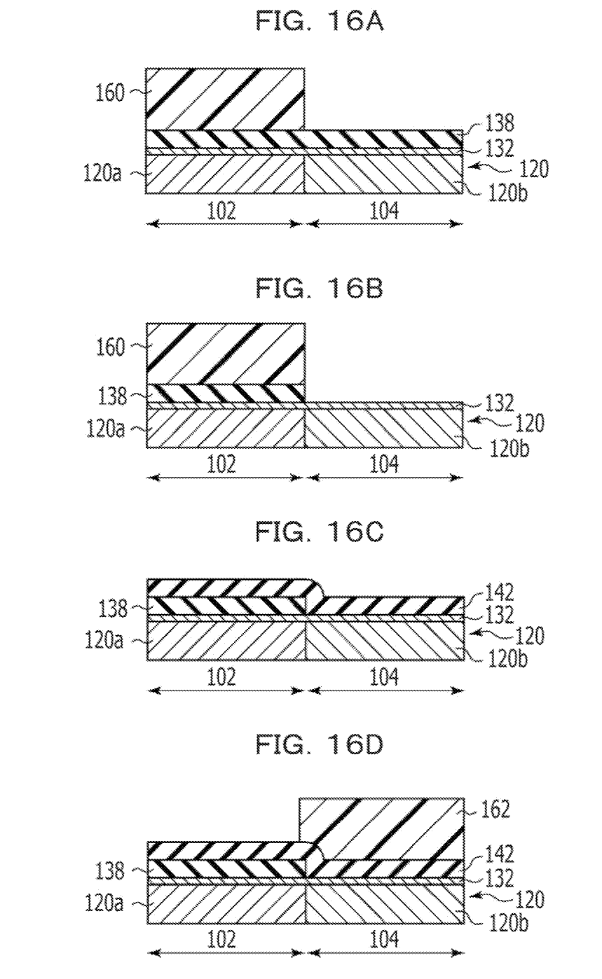

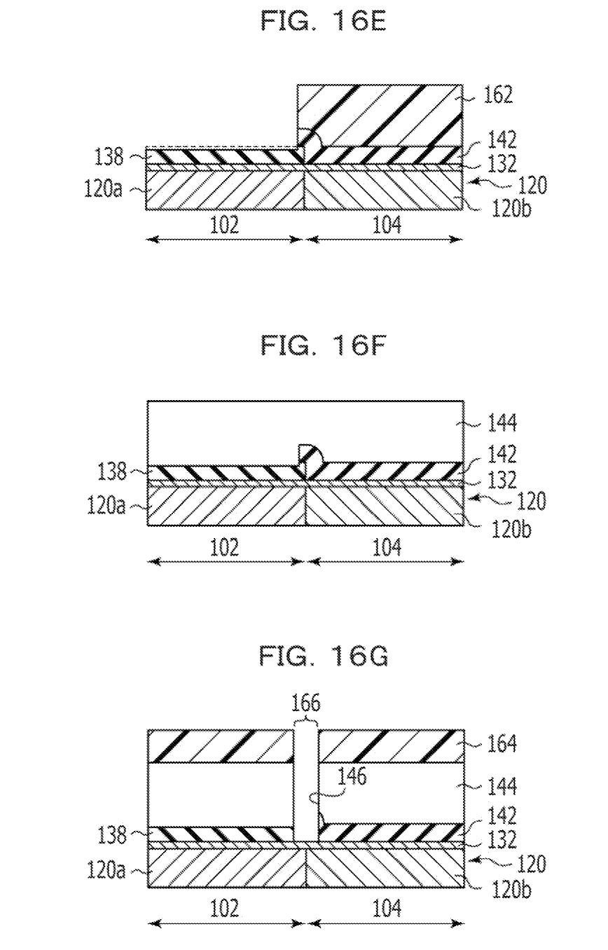

FIGS. 16A to 16G are cross sectional views illustrating steps in an exemplary process for forming a contact hole in a gate wiring of a CMOS circuit. In FIGS. 16A to 16G, a portion under a gate wiring 120 is omitted.

In an NMOS transistor region 102 and a PMOS transistor region 104, a gate wiring 120, which is to become a gate electrode 120a of the NMOS transistor and a gate electrode 120b of the PMOS transistor is formed (see FIG. 16A). On the gate wiring 120, a silicide layer 132 is formed. On the semiconductor substrate (not illustrated) on which the NMOS transistor and the PMOS transistor are formed, a tensile stress film 138 is formed on the entire surface thereof. On the tensile stress film 138, a photoresist film 160 covering the NMOS transistor region 102 and exposing the PMOS transistor region 104 is formed.

Next, as illustrated in FIG. 16B, the tensile stress film 138 is etched using the photoresist film 160 as a mask.

Next, as illustrated in FIG. 16C, a compressive stress film 142 is formed on the entire surface.

Next, as illustrated in FIG. 16D, a photoresist film 162 is formed on the compressive stress film 142. The photoresist film 162 is formed in such a manner as to cover not only the PMOS transistor region 104 but a portion adjacent to the PMOS transistor region 104 of the NMOS transistor region 102.

Next, as illustrated in FIG. 16E, the compressive stress film 142 is etched using the photoresist film 162 as a mask. Since the photoresist film 162 is formed in such a manner as to cover a part of the NMOS transistor region 102, the end surface at the side of the NMOS transistor region 102 of the compressive stress film 142 is located on the tensile stress film 138. When etching the compressive stress film 142, a certain degree of over-etching is performed, and thus the upper layer of the tensile stress film 138 is also etched. Therefore, as illustrated in FIG. 16E, the thickness of the tensile stress film 138 becomes small.

Next, as illustrated in FIG. 16F, an interlayer insulation film 144 is formed on the entire surface.

Next, as illustrated in FIG. 16G, a photoresist film 164 in which an opening 166 is formed is formed.

Next, the interlayer insulation film 144 and the like are etched using the photoresist film 164 as a mask to form a contact hole 146 that reaches the gate wiring 120.

Thus, in the method for manufacturing a semiconductor device illustrated in FIGS. 16A to 16G, when etching the compressive stress film 142, the upper layer of the tensile stress film 138 is also etched to reduce the thickness of the tensile stress film 138. When the thickness of the tensile stress film 138 becomes small, a stress to be applied to a channel region of the NMOS transistor becomes small, resulting in the fact that the carrier mobility may not sufficiently increase in some cases.

In order to prevent the upper layer of the tensile stress film 138 from being etched when etching the compressive stress film 142, it has been proposed to form an etching stopper film on the tensile stress film 138.

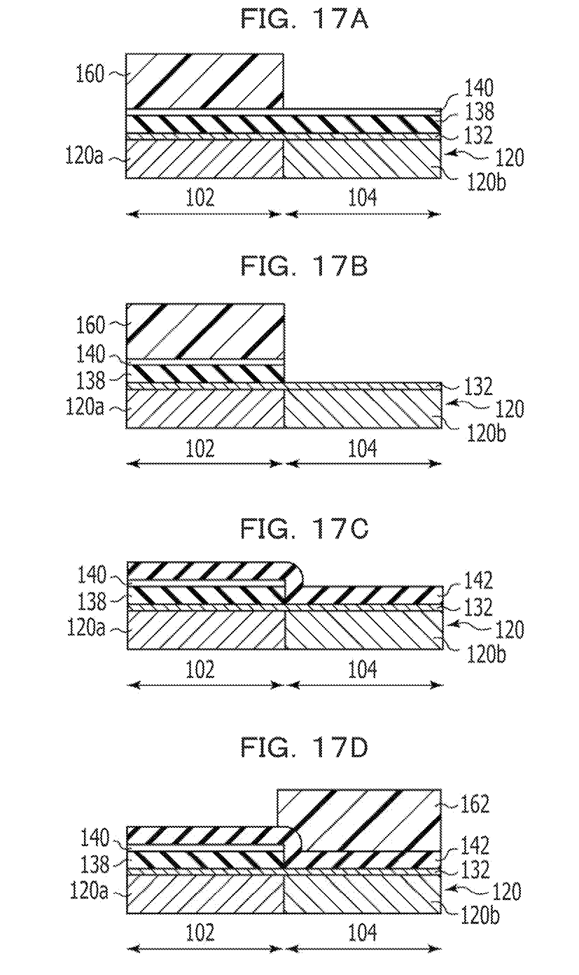

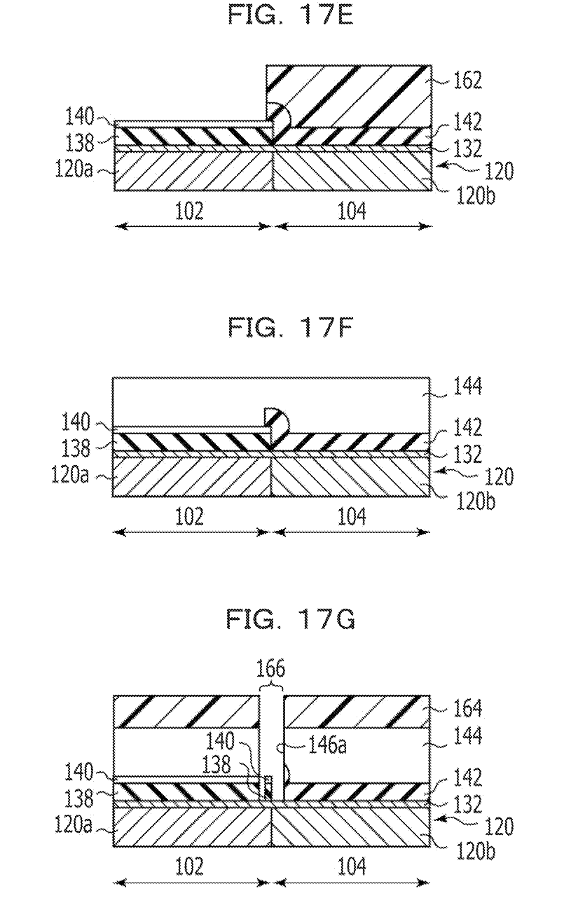

FIGS. 17A to 17G are cross sectional views illustrating steps in a process for forming a contact hole when the etching stopper film is formed on the stress film. In FIGS. 17A to 17G, a portion under the gate wiring 120 is omitted.

In the NMOS transistor region 102 and the PMOS transistor region 104, a gate wiring 120, which is to become a gate electrode 120a of the NMOS transistor and a gate electrode 120b of the PMOS transistor is formed (see FIG. 17A). On the gate wiring 120, a silicide layer 132 is formed. On a semiconductor substrate (not illustrated) on which the NMOS transistor and the PMOS transistor are formed, a tensile stress film 138 is formed on the entire surface thereof. On the tensile stress film 138, an etching stopper film 140 is formed. On the etching stopper film 140, a photoresist film 160 covering the NMOS transistor region 102 and exposing the PMOS transistor region 104 is formed.

Next, as illustrated in FIG. 17B, the etching stopper film 140 and the tensile stress film 138 are etched using the photoresist film 160 as a mask.

Next, as illustrated in FIG. 17C, a compressive stress film 142 is formed on the entire surface.

Next, a photoresist film 162 is formed on the compressive stress film 142. The photoresist film 162 is formed in such a manner as to cover not only the PMOS transistor region 104 but a portion adjacent to the PMOS transistor region 104 of the NMOS transistor region 102.

Next, as illustrated in FIG. 17D, the compressive stress film 142 is etched using the photoresist film 162 as a mask and using the etching stopper film 140 as an etching stopper. Since the photoresist film 162 is formed in such a manner as to cover a part of the NMOS transistor region 102, the end surface at the side of the NMOS transistor region 102 of the compressive stress film 142 is located on the etching stopper film 140. The etching of the compressive stress film 142 stops at the etching stopper film 140; the tensile stress film 138 is not etched.

Next, as illustrated in FIG. 17F, an interlayer insulation film 144 is formed on the entire surface.

Next, as illustrated in FIG. 17G, a photoresist film 164 in which an opening 166 is formed is formed.

Next, the interlayer insulation film 144 or the like is etched using the photoresist film 164 as a mask to form a contact hole 146a that reaches the gate wiring 120.

When the contact hole 146a that reaches the gate wiring 120 is formed as described above, a part of the etching stopper film 140 is present in a part of a portion where the contact hole 146a is to be formed, and thus etching is blocked by the etching stopper film 140. Therefore, as illustrated in FIG. 17G, there is a possibility that the cross sectional area of the contact hole 146a becomes relatively small at the lower portion of the contact hole 146a or opening defects occur.

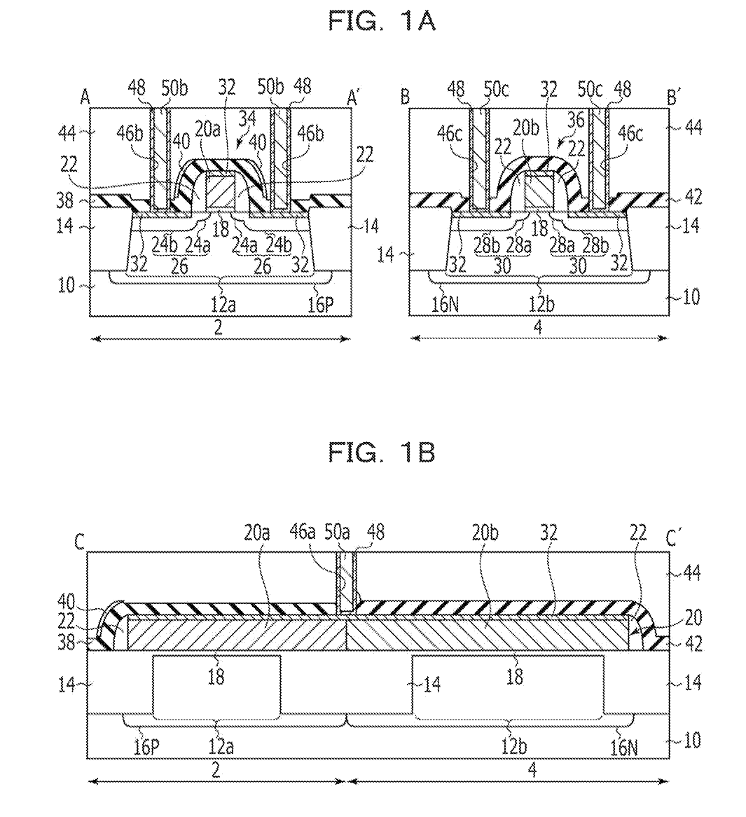

A semiconductor device according to one embodiment and a method for manufacturing the same will be described with reference to FIGS. 1 to 15.

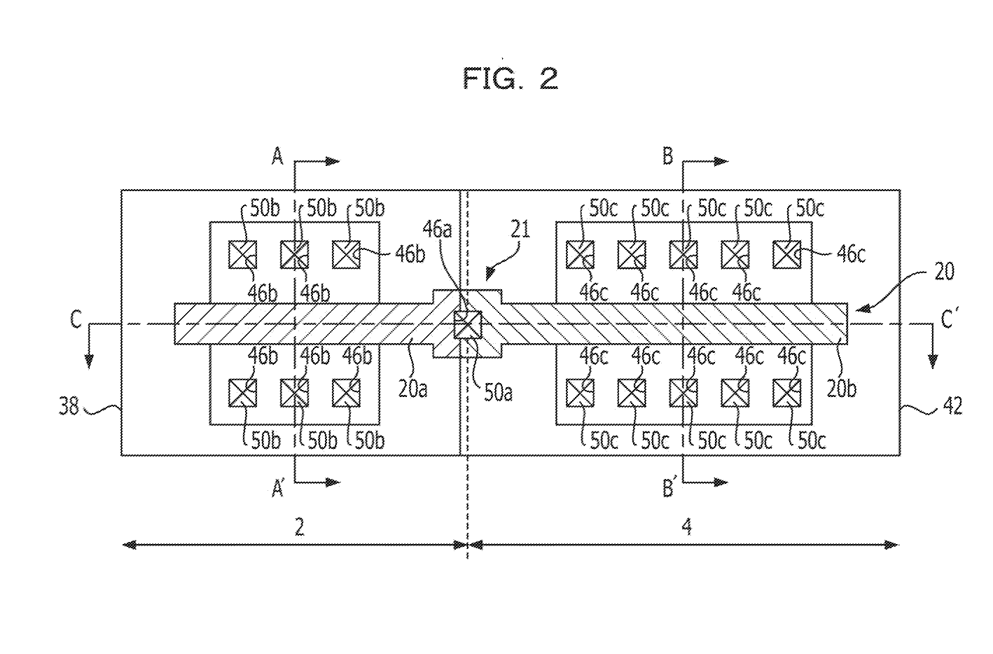

First, a semiconductor device according to this embodiment will be described with reference to FIGS. 1 to 3. FIGS. 1A and 1B are cross sectional views illustrating the semiconductor device according to this embodiment. FIG. 2 is a plan view illustrating the semiconductor device according to this embodiment. The left-side drawing of FIG. 1A represents an NMOS transistor region (first transistor region) 2 and corresponds to the cross section along the line A-A′ in FIG. 2. The right-side drawing of FIG. 1A represents a PMOS transistor region (second transistor region) 4 and corresponds to the cross section along the line B-B′ in FIG. 2. FIG. 1B is a cross sectional view along a gate wiring and corresponds to the cross section along the line C-C′ in FIG. 2.

As illustrated in FIGS. 1A and 1B, element isolation regions 14 for defining element regions 12a and 12b are formed on the semiconductor substrate 10. As the semiconductor substrate 10, a p-type silicon substrate is used, for example. In the NMOS transistor region 2 and the PMOS transistor region 4, the element regions 12a and 12b each defined by the element isolation regions 14 are formed, respectively.

A p-type well 16P is formed in the semiconductor substrate 10 in the NMOS transistor region 2. An n-type well 16N is formed in the semiconductor substrate 10 in the PMOS transistor region 4.

A gate electrode 20a in the NMOS transistor region 2 is formed on a gate insulation film 18. A gate electrode 20b in the PMOS transistor region 4 is formed on the gate insulation film 18. As the gate insulation film 18, a silicon nitride oxide film is used, for example.

The gate electrode 20a and the gate electrode 20b form a part of a gate wiring 20 continuously formed in the NMOS transistor region 2 and the PMOS transistor region 4. As the gate wiring 20, a polysilicon film or the like is used, for example. The gate wiring 20 may have a silicide layer 32 and the like formed on this polysilicon film. The width of the gate wiring 20 is about 30 to 35 nm, for example.

In the gate wiring 20 at the boundary between the NMOS transistor region 2 and the PMOS transistor region 4, a broad portion (connecting portion) 21 is formed. The width of the gate wiring 20 at the boundary between the NMOS transistor region 2 and the PMOS transistor region 4 is larger than the width of the gate wiring 20 in the element regions 12a and 12b. Such a broad portion 21 is formed in the gate wiring 20, so that a contact hole 46a in which a conductor plug 50a is to be embedded is formed in such a manner as to reach the boundary between the NMOS transistor region 2 and the PMOS transistor region 4.

An n-type dopant is introduced into the gate wiring 20 in the NMOS transistor region 2, and thus, the gate electrode 20a of the NMOS transistor 34 is formed. A p-type dopant is introduced into the gate wiring 20 in the PMOS transistor region 4, and thus, the gate electrode 20b of the PMOS transistor 36 is formed. Thus, the inside of the NMOS transistor region 2 of the gate wiring 20 serves as the gate electrode 20a of the NMOS transistor 34 and the inside of the PMOS transistor region 4 of the gate wiring 20 serves as the gate electrode 20b of the PMOS transistor 36.

The boundary between the gate electrode 20a of the NMOS transistor 34 and the gate electrode 20b of the PMOS transistor 36 is in agreement with the boundary between the NMOS transistor region 2 and the PMOS transistor region 4.

Sidewall insulation films 22 are formed at side walls of the gate wiring 20, i.e., side walls of the gate electrode 20a of the NMOS transistor 34 and side walls of the gate electrode 20b of the PMOS transistor 36. As materials of the sidewall insulation films 22, a silicon oxide film is used, for example. The thickness of the sidewall insulation films 22 is about 70 nm, for example.

In the semiconductor substrate 10 at both sides of the gate electrode 20a at which the sidewall insulation films 22 are formed, source/drain diffusion layers 26 having a low concentration impurity diffusion layer (extension region) 24a and a high concentration impurity diffusion layer 24b are formed. A portion between the source diffusion layer 26 and the drain diffusion layer 26 serves as a channel region of the NMOS transistor 34.

In the semiconductor substrate 10 at both sides of the gate electrode 20b at which the sidewall insulation films 22 are formed, source/drain diffusion layers 30 having a low concentration impurity diffusion layer (extension region) 28a and a high concentration impurity diffusion layer 28b are formed. A portion between the source diffusion layer 30 and the drain diffusion layer 30 serves as a channel region of the PMOS transistor 36.

On each of the gate wiring 20 and the source/drain diffusion layers 26 and 30, the silicide layer 32 is formed. A nickel silicide layer, a cobalt silicide layer, or the like is used as the silicide layer 32. The silicide layer 32 on the source/drain diffusion layers 26 and 30 function as source/drain electrodes. The silicide layer 32 on the gate wiring 20 aims at reducing the resistance of the gate wiring 20.

Thus, the PMOS transistor 34 having the gate electrode 20a, the source/drain diffusion layers 26, and the like is formed in the NMOS transistor region 2. The PMOS transistor 36 having the gate electrode 20b, the source/drain diffusion layers 30, and the like is formed in the PMOS transistor region 4.

On the semiconductor substrate 10 in the NMOS transistor region 2, a stress film (first stress film, stress film) 38 is formed in such a manner as to cover the NMOS transistor 34. The stress film 38 applies a tensile stress to the channel region of the NMOS transistor 34 and aims at improving the carrier mobility. As the stress film (tensile stress film) 38, a silicon nitride film is used, for example. The thickness of the stress film 38 is about 70 nm, for example. The end surface at the side of the PMOS transistor region 4 of the stress film 38 is located at the boundary between the NMOS transistor region 2 and the PMOS transistor region 4.

Etching stopper films (insulation film) 40 having etching characteristics different from those of the stress film 38 are formed in such a manner as to cover the portions covering the sidewall insulation film 22s of the stress film 38. More specifically, the etching stopper films 40 are selectively formed on portions covering the sidewall insulation films 22 of the stress film 38. The etching stopper films 40 function as etching stoppers when a stress film (second stress film) 42 described later is etched. As the etching stopper films 40, a silicon oxide film is used, for example. The thickness of the etching stopper films 40 is about 25 nm, for example.

On the semiconductor substrate 10 in the PMOS transistor region 4, the stress film (second stress film, stress film) 42 is formed in such a manner as to cover the PMOS transistor 36. The stress film 42 applies a stress to the channel region of the PMOS transistor 36 and aims at improving the carrier mobility. The etching characteristics of the stress film (compressive stress film) 42 are different from the etching characteristics of the etching stopper film 40. As the stress film 42, a silicon nitride film is used, for example. The thickness of the stress film 42 is 60 to 80 nm, for example. The edge at the side of the NMOS transistor region 2 of the stress films 42 is overlapped with a portion of the stress film 38.

The thickness of portions not covered with the etching stopper films 40 of the stress film 38 is sometimes smaller than the thickness of the portions covered with the etching stopper films 40 of the stress film 38. This is because the upper layer of the stress film 38 is etched to a certain degree due to over-etching when patterning the stress film 42.

FIG. 3 is a graph illustrating the simulation results of strain generated in the channel region. The axis of abscissa of FIG. 3 represents the thickness of the stress film 38 at flat portions. More specifically, the axis of abscissa of FIG. 3 represents the thickness of the stress film 38 on the source/drain diffusion layers 26 or the element isolation region 14. The axis of ordinates of FIG. 3 represents the size of strain generated on the surface at the central portion of the channel region of the transistor 34. The plot in FIG. 3 represents the case where the thickness of the portions covering the sidewall insulation films 22 of the stress film 38 is 60 nm. The plot ▴ in FIG. 3 represents the case where the thickness of the portions covering the sidewall insulation films 22 of the stress film 38 is 70 nm. The plot ◯ in FIG. 3 represents the case where the thickness of the portions covering the sidewall insulation films 22 of the stress film 38 is 80 nm.

As is understood from FIG. 3, the stress generating in the channel region of the transistor 34 is hardly dependent on the thickness of the stress film 38 at the flat portions.

In contrast, the stress generating in the channel region of the transistor 34 is considerably dependent on the thickness of the portions covering the sidewall insulation films 22 of the stress film 38.

It is considered that the fact that the stress generating in the channel region is considerably dependent on the thickness of the portions covering the sidewall insulation films 22 of the stress film 38 and is hardly dependent on the thickness of the stress films 38 at the flat portions relates to the distance with the channel region.

More specifically, the portions covering the sidewall insulation films 22 of the stress film 38 are adjacent to the channel region, and thus a reduction in the thickness in such portions causes a reduction in the stress to be applied to the channel region.

In contrast, since the stress film 38 present in the flat portion is separated from the channel region, a reduction in the thickness in such a portion hardly causes a reduction in the stress to be applied to the channel region.

This indicates that when the portions covering the sidewall insulation films 22 of the stress film 38 are prevented from being etched, a sufficient stress may be applied to the channel region even when the stress film 38 other than the portions is etched to a certain degree.

Therefore, even when the portions not covering the sidewall insulation film 22 of the stress film 38 are etched to a certain degree as illustrated in FIGS. 1A and 1B, the stress to be applied to the channel region hardly decreases and the transistor 34 having a high carrier mobility may be obtained.

An interlayer insulation film 44 is formed on the semiconductor substrate 10 on which the stress film 38, the etching stopper film 40, and the stress film 42 are formed. The surface of the interlayer insulation film 44 is flattened. The thickness of the interlayer insulation film 44 is about 350 to 400 nm, for example. As the interlayer insulation film 44, a silicon oxide film or the like is used, for example.

The contact hole 46a that reaches the gate wiring 20 is formed in the interlayer insulation film 44, the stress film 42, and the stress film 38. The contact hole 46a is formed in such a manner as to reach the gate wiring 20 at the boundary between the NMOS transistor region 2 and the PMOS transistor region 4. The contact hole 46a is located above the element isolation region 14 located between the element region 12a and the element region 12b. The contact hole 46a penetrates the interlayer insulation film 44, the stress film 42, and the stress film 38.

In this embodiment, the reason why the contact hole 46a is formed in such a manner as to reach the gate wiring 20 at the boundary between the NMOS transistor region 2 and the PMOS transistor region 4 is as follows. More specifically, when the contact hole 46a is formed at a portion deviated from the boundary between the NMOS transistor region 2 and the PMOS transistor region 4, the size of either the NMOS transistor region 2 or the PMOS transistor region 4 becomes large. In order to reduce the size of the NMOS transistor region 2 and the PMOS transistor region 4 to reach the minimum, the contact hole 46a that reaches the gate wiring 20 is preferably disposed at the boundary between the NMOS transistor region 2 and the PMOS transistor region 4. For such reasons, according to this embodiment, the contact hole 46a is formed in such a manner as to reach the gate wiring 20 at the boundary between the NMOS transistor region 2 and the PMOS transistor region 4.

Contact holes 46b that reach the silicide layer 32 on the source/drain diffusion layers of the NMOS transistor 34 are formed in the interlayer insulation film 44 and the stress film 38 in the NMOS transistor region 2.

Contact holes 46c that reach the silicide layer 32 on the source/drain diffusion layers of the PMOS transistor 36 are formed in the interlayer insulation film 44 and the stress film 42 in the PMOS transistor region 4.

Barrier metal films 48 are formed at the bottom surface and the side surfaces of the contact holes 46a to 46c. The barrier metal films 48 are formed by successively laminating a Ti film (not illustrated) and a TiN film (not illustrated), for example.

In the contact holes 46a to 46c at which the barrier metal films 48 are formed, conductor plugs 50a to 50c are embedded, respectively. As materials of the conductor plugs 50a to 50c, tungsten (W) is used, for example. The conductor plug 50a is connected to the gate wiring 20 at the boundary between the NMOS transistor region 2 and the PMOS transistor region 4. The conductor plugs 50b are connected to the silicide layer 32 on the source/drain diffusion layers of the NMOS transistor 34. The conductor plugs 50c are connected to the silicide layer 32 on the source/drain diffusion layers of the PMOS transistor 36.

On the interlayer insulation film 44 in which the conductor plugs 50a to 50c are embedded, wiring (not illustrated) and the like connected to the conductor plugs 50a to 50c is formed.

Thus, a semiconductor device including a CMOS circuit having the PMOS transistor 34 and the NMOS transistor 36 is formed.

As described above, according to this embodiment, the etching stopper films 40 are alternatively formed on the portion covering the sidewall insulation films 22 of the stress film 38 and the etching stopper film 40 is removed from the boundary between the NMOS transistor region 2 and the PMOS transistor region 4. Therefore, according to this embodiment, etching is not blocked with the etching stopper films 40, and the contact hole 46a is securely formed in such a manner as to reach the gate wiring 20 at the boundary between the NMOS transistor region 2 and the PMOS transistor region 4. Thus, according to this embodiment, the favorable contact hole 46a penetrating the interlayer insulation film 44, the stress film 42, and the stress film 38 is formed. Since the conductor plug 50a is embedded in the contact hole 46a, the conductor plug 50a and the gate wiring 20 are securely connected to each other. Moreover, according to this embodiment, the etching stopper films 40 are selectively formed on the portions covering the sidewall insulation films 22 of the stress film 38, and thus the portions covering the sidewall insulation films 22 of the stress film 38 are not etched. A reduction in the thickness of the stress film 38 in a portion adjacent to the channel region causes a considerable reduction in the stress to be applied to the channel region. In contrast, even when the thickness of the stress film 38 becomes small at a portion separated from the channel region, the considerable reduction in the stress to be applied to the channel region is not caused. Therefore, when the portions covering the sidewall insulation films 22 of the stress film 38 are prevented from being etched as in this embodiment, a sufficient stress may be applied to the channel region. Therefore, according to this embodiment, a high-reliable semiconductor device may be provided with a high manufacturing yield while achieving the improvement of the carrier mobility of the transistor 34.

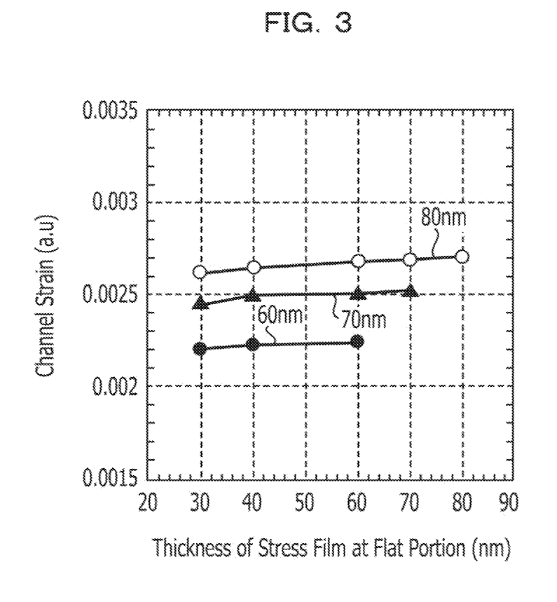

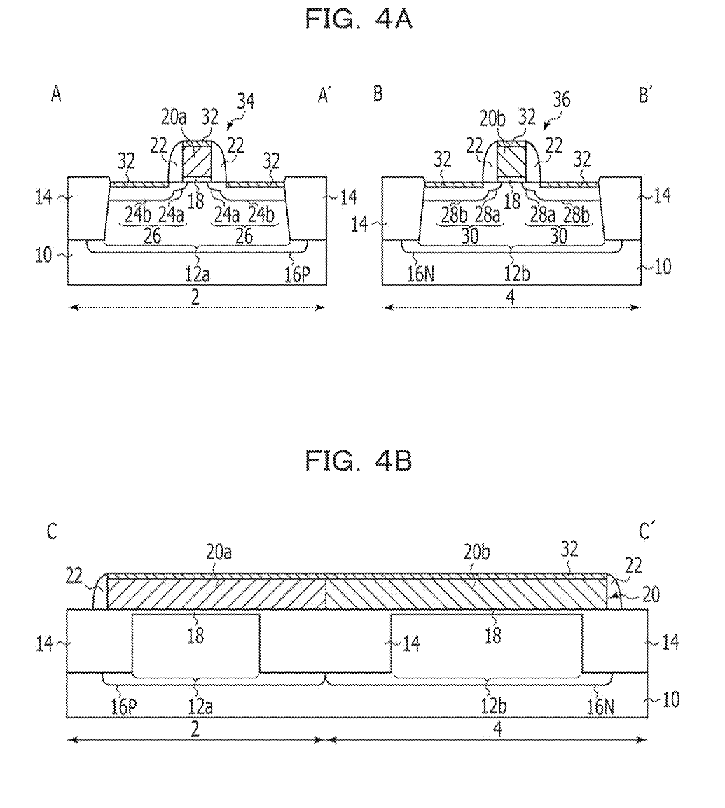

Next, a method for manufacturing a semiconductor device according to this embodiment will be described with reference to FIGS. 4 to 15. FIGS. 4 to 15 are cross sectional views illustrating steps in a process for manufacturing a semiconductor device according to this embodiment. The left-side drawings on FIGS. 4A, 5A, 6A, 7A, 8A, 9A, 10A, 11A, 12A, 13, and 15A illustrate the NMOS transistor region 2 and correspond to the cross section along the A-A′ line in FIG. 2. The right-side drawings on FIGS. 4A, 5A, 6A, 7A, 8A, 9A, 10A, 11A, 12A, 13, and 15A illustrate the PMOS transistor region 4 and correspond to the cross section along the B-B′ line in FIG. 2. FIGS. 4B, 5B, 6B, 7B, 8B, 9B, 10B, 11B, 12B, 14, and 15B are cross sectional views along the gate wiring 20 and correspond to the cross section along the C-C′ line in FIG. 2.

First, for example, the element isolation region 14 that defines the element regions 12a and 12b are formed on the semiconductor substrate 10 by an STI (Shallow Trench Isolation) method (see FIG. 4A). As the semiconductor substrate 10, a p-type silicon substrate is used, for example. Thus, the element region 12a defined by the element isolation regions 14 is formed in the NMOS transistor region 2. Moreover, the element region 12b defined by the element isolation regions 14 is formed in the PMOS transistor region 4.

Next, a photoresist film (not illustrated) is formed on the entire surface by a spin coat method, for example.

Next, an opening (not illustrated) that exposes the NMOS transistor region 2 is formed in the photoresist film using a photolithographic technique.

Next, a p-type dopant is introduced into the semiconductor substrate 10 by ion implantation, for example, using the photoresist film as a mask. Thus, a p-type well 16P is formed in the semiconductor substrate 10 in the NMOS transistor region 2. Thereafter, the photoresist film is removed by ashing, for example.

Next, a photoresist film (not illustrated) is formed on the entire surface by a spin coat method, for example.

Next, an opening (not illustrated) that exposes the PMOS transistor region 4 is formed in the photoresist film using a photolithographic technique.

Next, an n-type dopant is introduced into the semiconductor substrate 10 by ion implantation, for example, using the photoresist film as a mask. Thus, an n-type well 16N is formed in the semiconductor substrate 10 in the PMOS transistor region 4. Thereafter, the photoresist film is removed by ashing, for example.

Next, a gate insulation film 18 is formed on the surface of the semiconductor substrate 10 by a thermal oxidation method, for example. As the gate insulation film 18, a silicon nitride oxide film is formed, for example. The thickness of the gate insulation film 18 is 1.3 to 1.4 nm, for example.

Next, a polysilicon film is formed on the entire surface by a CVD (Chemical Vapor Deposition) method. The polysilicon film serves as the gate wiring 20. The thickness of the polysilicon film is 100 nm, for example.

Next, a photoresist film (not illustrated) is formed on the entire surface by a spin coat method, for example.

Next, the photoresist film is patterned into a plane shape of the gate wiring 20 using a photolithographic technique.

Next, a polysilicon film is etched using a photoresist film as a mask. Thus, the gate wiring 20 formed with the polysilicon film is continuously formed in the NMOS transistor region 2 and the PMOS transistor region 4.

The gate wiring 20 is broadly formed in a region adjacent to the boundary between the NMOS transistor region 2 and the PMOS transistor region 4, i.e., the boundary (see FIG. 2). More specifically, a broad portion (connecting portion) 21 is formed in the gate wiring 20 at the boundary between the NMOS transistor region 2 and the PMOS transistor region 4. The reason why the width of the gate wiring 20 at the boundary between the NMOS transistor region 2 and the PMOS transistor region 4 is relatively widely set as described above resides in the fact that the contact hole 46a is formed in such a manner as to reach the broad portion. The width of the gate wiring 20 at the portion except the broad portion 21 is about 30 to 35 nm. The width of the gate wiring 20 at the broad portion 21 is about 30 to 35 nm. Thereafter, the photoresist film is removed by ashing, for example.

Next, a photoresist film (not illustrated) is formed on the entire surface by a spin coat method, for example.

Next, an opening (not illustrated) that exposes the NMOS transistor region 2 is formed in the photoresist film using a photolithographic technique.

Next, an n-type dopant is introduced into the semiconductor substrate 10 by ion implantation, for example, using the photoresist film and the gate wiring 20 as a mask. Thus, n-type low concentration impurity regions (extension region) 24a are formed in the semiconductor substrate 10 at both sides of the gate wiring 20 in the NMOS transistor region 2. Thereafter, the photoresist film is removed by ashing, for example.

Next, a photoresist film (not illustrated) is formed on the entire surface by a spin coat method, for example.

Next, an opening (not illustrated) that exposes the PMOS transistor region 4 is formed in the photoresist film using a photolithographic technique.

Next, a p-type dopant is introduced into the semiconductor substrate 10 by ion implantation, for example, using the photoresist film and the gate wiring 20 as a mask. Thus, p-type low concentration impurity regions (extension region) 28a are formed in the semiconductor substrate 10 at both sides of the gate wiring 20 in the PMOS transistor region 4. Thereafter, the photoresist film is removed by ashing, for example.

Next, an insulation film is formed on the entire surface by a CVD method, for example. The insulation film serves as a sidewall insulation film. As such an insulation film, a silicon oxide film is formed, for example. The thickness of the insulation film is 70 nm, for example.

Next, the insulation film is etched by anisotropic etching, for example. Thus, the sidewall insulation films 22 are formed at the side walls of the gate wiring 20.

Next, a photoresist film (not illustrated) is formed on the entire surface by a spin coat method, for example.

Next, an opening (not illustrated) that exposes the NMOS transistor region 2 is formed in the photoresist film using a photolithographic technique.

Next, an n-type dopant is introduced into the semiconductor substrate 10 by ion implantation, for example, using the photoresist film, the gate wiring 20, and the sidewall insulation films 22 as a mask. Thus, n-type high concentration impurity regions 24b are formed in the semiconductor substrate 10 at both sides of the gate wiring 20 in the NMOS transistor region 2. Thus, source/drain diffusion layers 26 having an extension sauce/drain structure are formed by the low concentration impurity regions (extension region) 24a and the high concentration impurity regions 24b. The region between the source diffusion layer 26 and the drain diffusion layer 26 serves as a channel region.

When the n-type dopant for forming the source/drain diffusion layers 26 is poured, the n-type dopant is also introduced into the gate wiring 20 in the NMOS transistor region 2. Thus, the portion in the NMOS transistor region 2 of the gate wiring 20 serves as the gate electrode 20a into which the n-type dopant has been introduced. Then, the photoresist film is removed by ashing, for example.

Next, a photoresist film (not illustrated) is formed on the entire surface by a spin coat method, for example.

Next, an opening (not illustrated) that exposes the PMOS transistor region 4 is formed in the photoresist film using a photolithographic technique.

Next, a p-type dopant is introduced into the semiconductor substrate 10 by ion implantation, for example, using the photoresist film, the gate wiring 20, and the sidewall insulation films 22 as a mask. Thus, p-type high concentration impurity regions 28b are formed in the semiconductor substrate 10 at both sides of the gate wiring 20 in the PMOS transistor region 4. Thus, source/drain diffusion layers 30 having an extension sauce/drain structure are formed by the low concentration impurity regions (extension region) 28a and the high concentration impurity regions 28b. The region between the source diffusion layer 30 and the drain diffusion layer 30 serves as a channel region.

When the p-type dopant for forming the source/drain diffusion layers 30 is poured, the p-type dopant is also introduced into the gate wiring 20 in the PMOS transistor region 4. Thus, the portion in the PMOS transistor region 4 of the gate wiring 20 serves as the gate electrode 20b into which the p-type dopant has been introduced. The boundary between the gate electrode 20a of the NMOS transistor 34 and the gate electrode 20b of the PMOS transistor 36 is in agreement with the boundary between the NMOS transistor region 2 and the PMOS transistor region 4. Thereafter, the photoresist film is removed by ashing, for example.

Next, a high melting point metal film is formed on the entire surface. As such a high melting point metal film, a nickel film, a cobalt film, or the like is formed, for example. The thickness of the high melting point metal film is about 10 nm, for example.

Next, the silicon atoms in the semiconductor substrate 10 and the metal atoms in the high melting point metal film are reacted by heat treating. Moreover, the silicon atoms in the gate wiring 20 and the metal atoms in the high melting point metal film are reacted. The heat treatment temperature is about 200 to 300° C., for example.

Next, an unreacted portion of the high melting point metal film is removed by etching.

Thus, the silicide layer 32 is formed on each of the source/drain diffusion layers 26 and 30. The silicide layer 32 formed on the source/drain diffusion layers 26 and 30 functions as source/drain electrodes. Moreover, the silicide layer 32 is also formed on the gate wiring 20.

Thus, the NMOS transistor 34 having the gate electrode 20a, the source/drain diffusion layers 26, and the like is formed in the NMOS transistor region 2. The PMOS transistor 36 having the gate electrode 20b, and source/drain diffusion layers 30, and the like is formed in the PMOS transistor region 4.

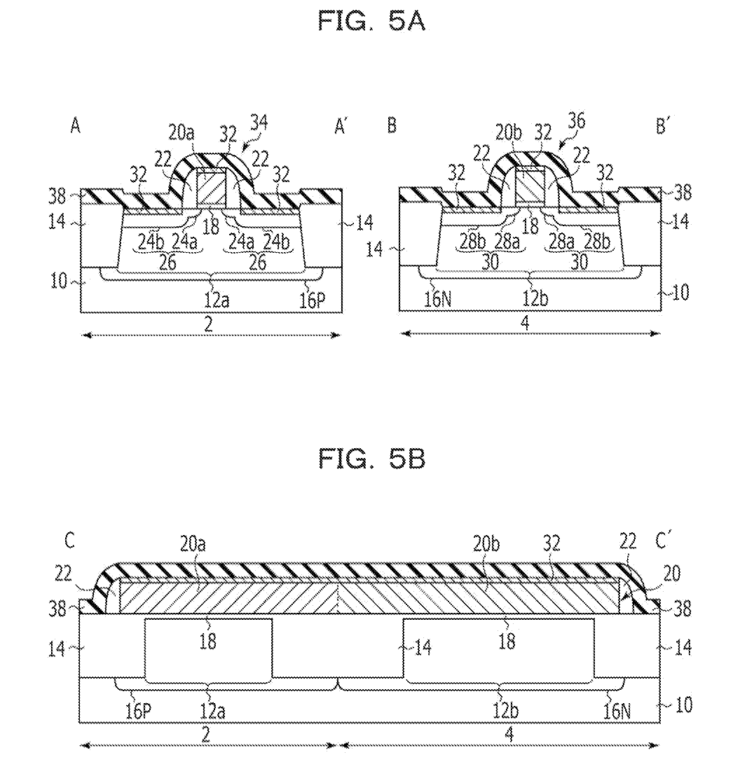

Next, the stress film (first stress film, stress film) 38 is formed on the entire surface by a plasma CVD method, for example (FIGS. 5A and 5B). The stress film 38 applies a tensile stress to the channel region of the NMOS transistor 34, and aims at improving the carrier mobility.

The stress film (pulling stress film) 38 may be formed as follows, for example. More specifically, the substrate temperature during the formation of the stress film 38 is about 400 to 450° C., for example. Into a film forming chamber, DCS (dichlorosilane, SiH₂Cl₂) gas, NH₃ gas, and N₂ gas are simultaneously supplied, for example. The flow rate of the DCS gas is 5 to 50 sccm, for example. The flow rate of the NH₃ gas is 500 to 1000 sccm, for example. The flow rate of the N₂ gas is 500 to 10000 sccm, for example. In place of the DCS gas, SiH₄ gas, Si₃H₈ gas, Si₂H₆ gas, or the like may be used. In place of the N₂ gas, Ar gas may be used. The pressure in the chamber is 0.1 to 400 Torr, for example. Thus, the compressive stress film 38 formed with the silicon nitride film is formed. The thickness of the compressive stress film 38 is about 70 nm, for example.

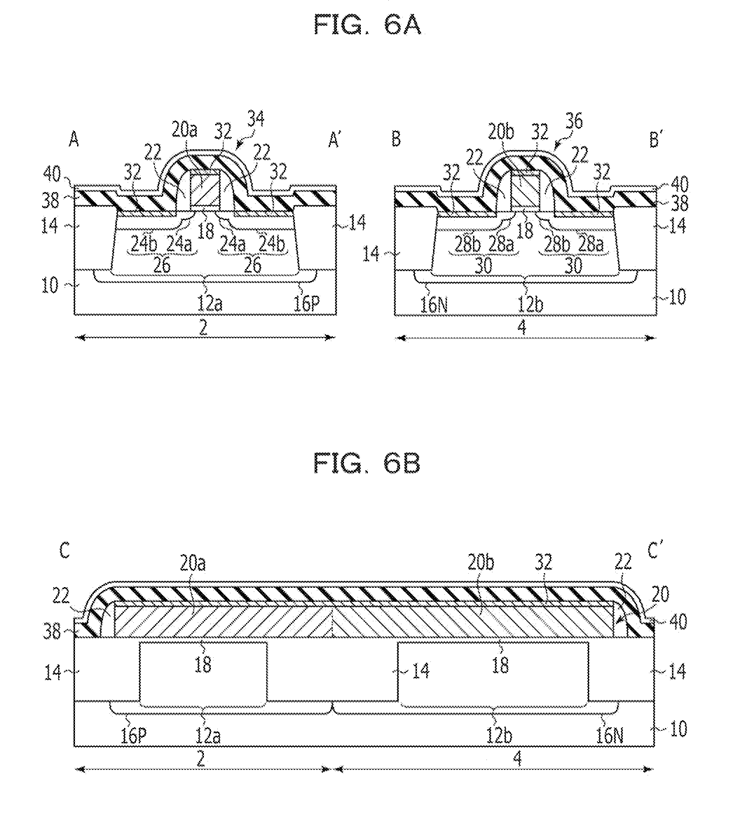

Next, the etching stopper (insulation film) 40 is formed on the entire surface by a plasma CVD method, for example (FIGS. 6A and 6B). The etching stopper film 40 functions as an etching stopper when a stress film (second stress film) 42 to be formed in the following process is etched. Accordingly, the etching characteristics of the etching stopper film 40 are different from the etching characteristics of the stress film 42 to be formed in the following process. The etching characteristics of the etching stopper film 40 are also different from the etching characteristics of the stress film 38 located under the etching stopper film 40. As the etching stopper film 40, a silicon oxide film is formed, for example. The film formation conditions of the etching stopper film 40 are as follows, for example. More specifically, the gas to be introduced into the film forming chamber is a mixed gas of SiH₄ gas and O₂ gas, for example. The substrate temperature is about 400° C., for example. The thickness of the etching stopper film 40 is about 25 nm, for example.

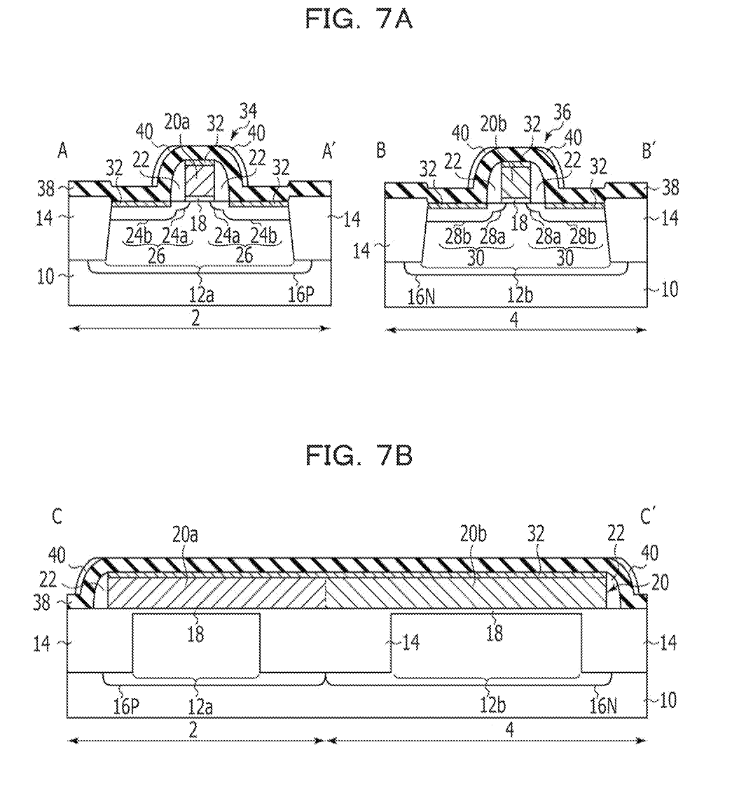

Next, the etching stopper film 40 is subjected to anisotropic etching by RIE (Reactive Ion Etching), for example (FIGS. 7A and 7B). The gases to be introduced into the chamber when performing the anisotropic etching of the etching stopper film 40 are C₄F₈ gas, Ar gas, and O₂ gas, for example. When etching is performed corresponding to the thickness of the etching stopper film 40 without performing over-etching, the etching stopper film 40 may be selectively left on the portions covering the sidewall insulation films 22 of the stress film 38. Thus, the etching stopper film 40 selectively remains on the portions covering the sidewall insulation films 22 of the stress film 38. In other words, the etching stopper film 40 remains only at the side walls of the gate electrodes 20a and 20b.

Next, a photoresist film 60 is formed on the entire surface by a spin coat method, for example.

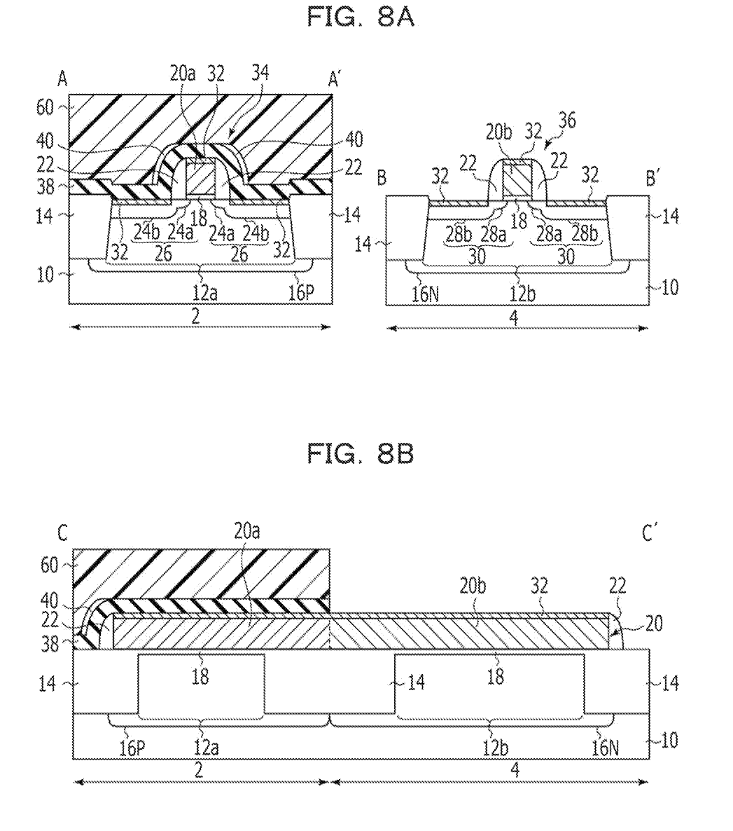

Next, the photoresist film 60 is patterned using a photolithographic technique (FIGS. 8A and 8B). Thus, the photoresist film 60 is formed that covers the NMOS transistor region 2 and exposes the PMOS transistor region 4. The end surface at the side of the PMOS transistor region 4 of the photoresist films 60 is located at the boundary between the NMOS transistor region 2 and the PMOS transistor region 4.

Next, the etching stopper film 40 and the stress film 38 are successively removed by etching using the photoresist film 60 as a mask.

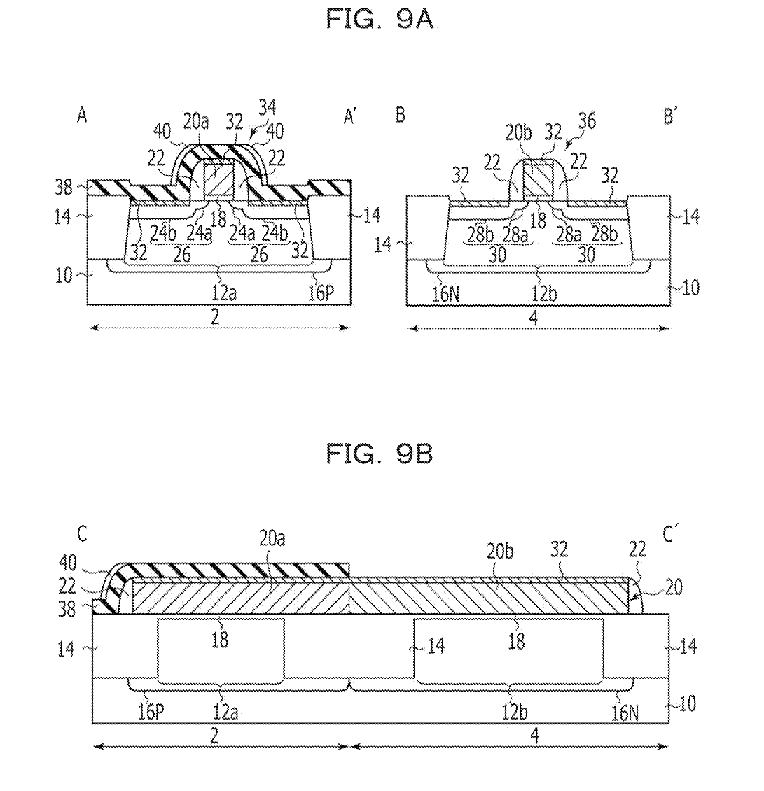

Next, the photoresist film 60 is removed by ashing, for example (FIGS. 9A and 9B).

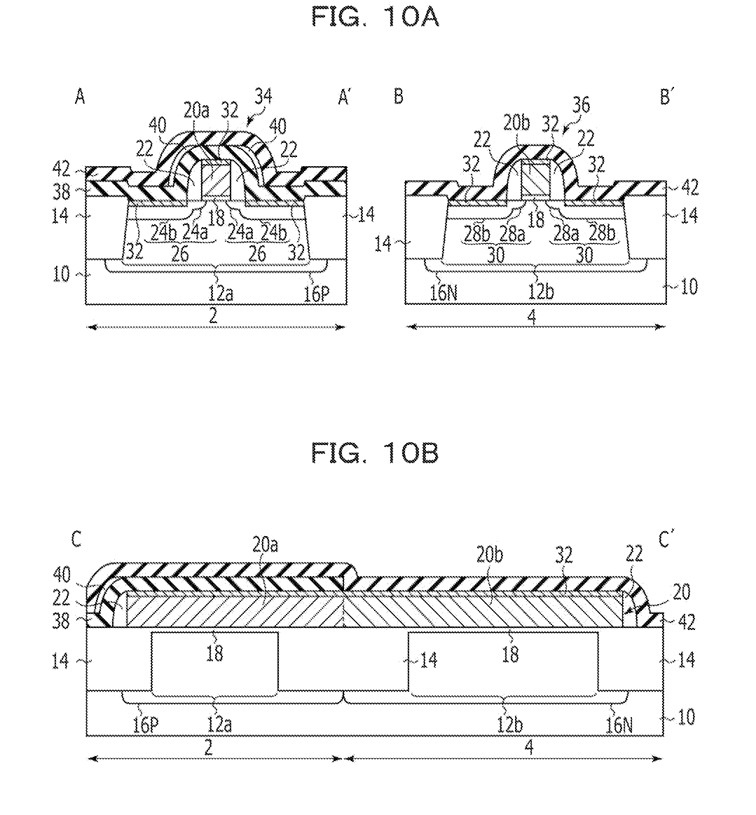

Next, the stress film (second stress film) 42 is formed on the entire surface by a plasma CVD method, for example (FIGS. 10A and 10B). The stress film (stress film) 42 applies a compressive stress to the channel region of the PMOS transistor 36, and aims at improving the carrier mobility.

The stress film (compressive stress film) 42 may be formed as follows, for example. More specifically, the stress film 42 is formed in a vacuum chamber using a parallel plate type plasma CVD apparatus, for example. The substrate temperature during the formation of the stress film 42 is about 400 to 450° C., for example. In a vacuum chamber, SiH₄ gas, NH₃ gas, and N₂ gas are simultaneously supplied, for example. The flow rate of the SiH₄ gas is 100 to 1000 sccm, for example. The flow rate of the NH₃ gas is 500 to 10000 sccm, for example. The flow rate of the N₂ gas is 500 to 10000 sccm, for example. In place of the N₂ gas, Ar gas may be used. The pressure in the chamber is 0.1 to 400 Torr, for example. The high frequency electric power to be applied is about 100 to 1000 W, for example.

Thus, the stress film 42 formed with the silicon nitride film is formed on the entire surface. The thickness of the stress film 42 is about 60 to 80 nm, for example. The etching characteristics of the stress film 42 are different from the etching characteristics of the etching stopper film 40.

Next, the photoresist film 62 is formed on the entire surface by a spin coat method, for example.

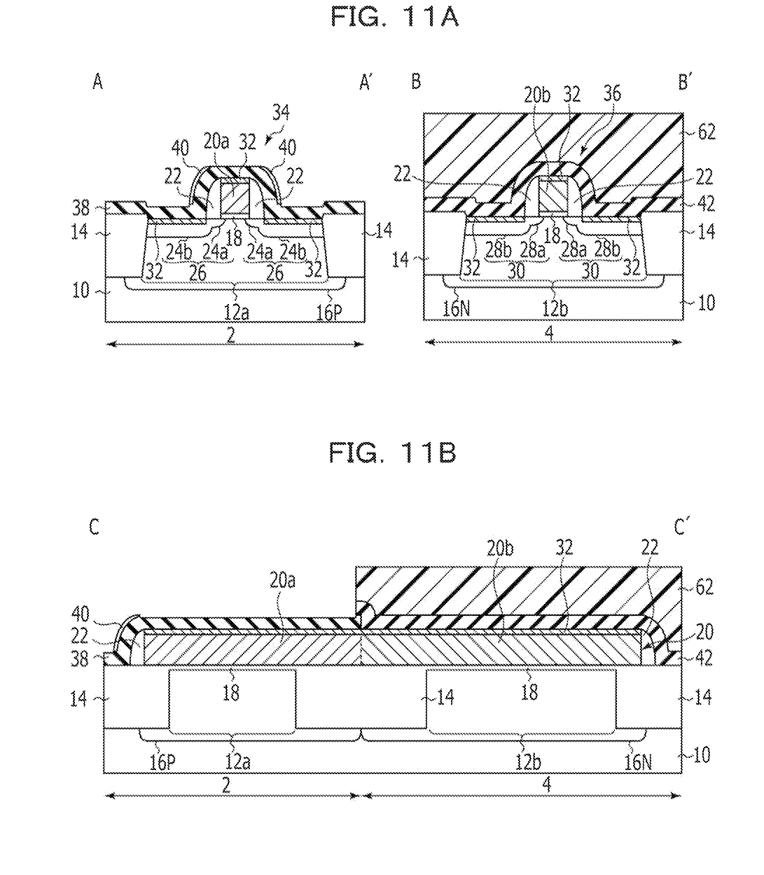

Next, a photoresist film 62 is patterned using a photolithographic technique (FIGS. 11A and 11B). The photoresist film 62 is formed in such a manner as to cover not only the PMOS transistor region 4 but a portion of NMOS transistor region 2. Specifically, the photoresist film 62 is formed in such a manner as to cover the PMOS transistor region 4 and is formed so that the end surface at the side of the NMOS transistor region 2 is located on the stress film 38.

Next, the stress film 42 is subjected to anisotropic etching using the photoresist film 62 as a mask and using the etching stopper film 40 as an etching stopper (FIGS. 11A and 11B). The anisotropic etching is performed in a vacuum chamber using a parallel plate type dry etching apparatus, for example. As the etching gas to be introduced into the vacuum chamber, a mixed gas of CHF₃ gas, Ar gas, and O₂ gas is used, for example. Thus, the stress film 42 is formed so that the end surface at the side of the NMOS transistor region 2 of the stress films 42 is located on the stress film 38. More specifically, the stress film 42 is formed so that a part of the stress film 42 is overlapped with a part of the stress film 38.

The portions covered with the etching stopper films 40 of the stress film 38 are not etched when the stress film 42 is etched, and the thickness does not become small. The portions not covered with the etching stopper film 40 of the stress film 38 are sometimes etched due to over-etching during etching of the stress film 42, and thus the thickness sometimes becomes small to a certain degree. Therefore, the thickness of the portions not covered with the etching stopper film 40 of the stress film 38 is sometimes smaller than that of the portions covered with the etching stopper films 40 of the stress film 38.

The stress film 38 at the portion adjacent to the channel region of the transistor 34 greatly contributes to the application of a stress (tensile stress) to the channel region but the stress film 38 of the portion separated from the channel region hardly contributes to the application of the stress to the channel region. Accordingly, when the thickness of the stress film 38 of the portion adjacent to the channel region, particularly the portion covering the sidewall insulation film 22 of the stress film 38, is sufficiently secured, a sufficient stress may be applied to the channel region to thereby sufficiently increase the carrier mobility of the transistor 34. Even when the stress film 38 of the portion not covered with the etching stopper film 40 becomes thin to a certain degree, the stress to be applied to the channel region does not remarkably decrease, and special problems do not arise.

Thereafter, the photoresist film 62 is removed by ashing, for example.

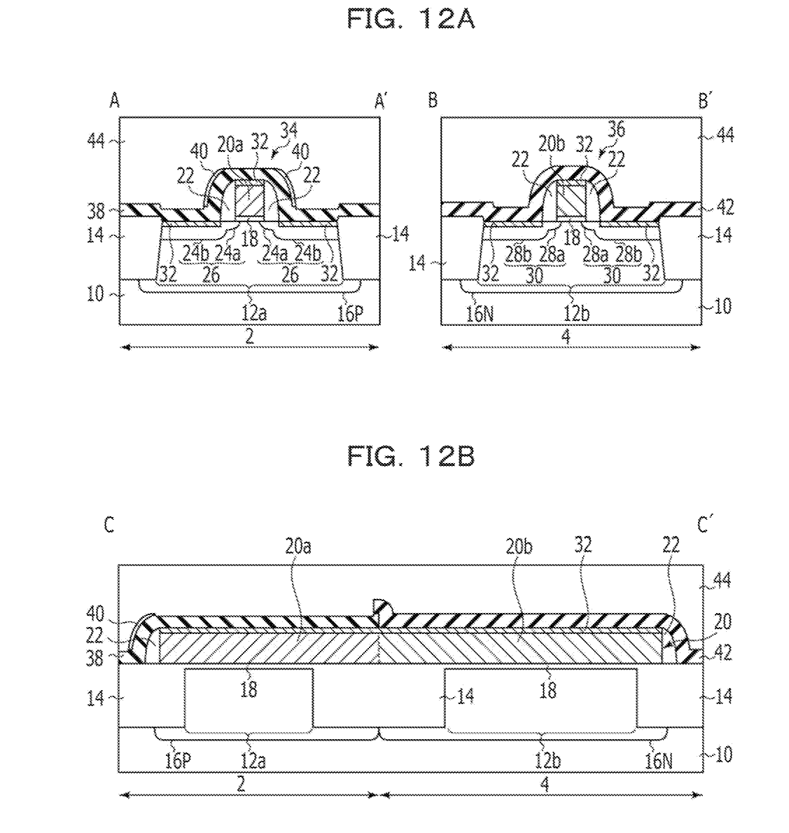

Next, the interlayer insulation film 44 is formed on the entire surface by a CVD method, for example (FIGS. 12A and 12B). The thickness of the interlayer insulation film 44 is about 500 to 600 nm, for example. As the interlayer insulation film 44, a silicon oxide film or the like is formed, for example.

Next, the surface of the interlayer insulation film 44 is flattened by a CMP (Chemical Mechanical Polishing) method.

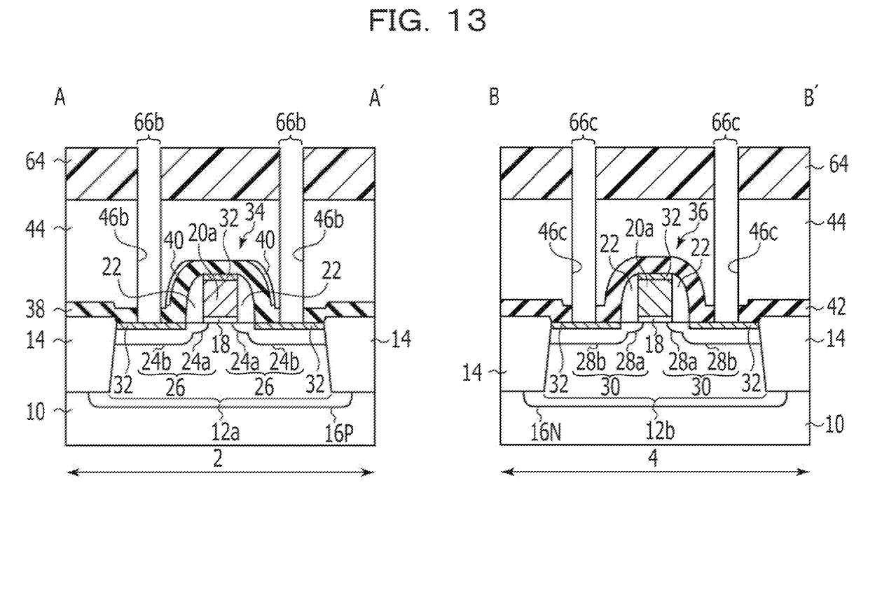

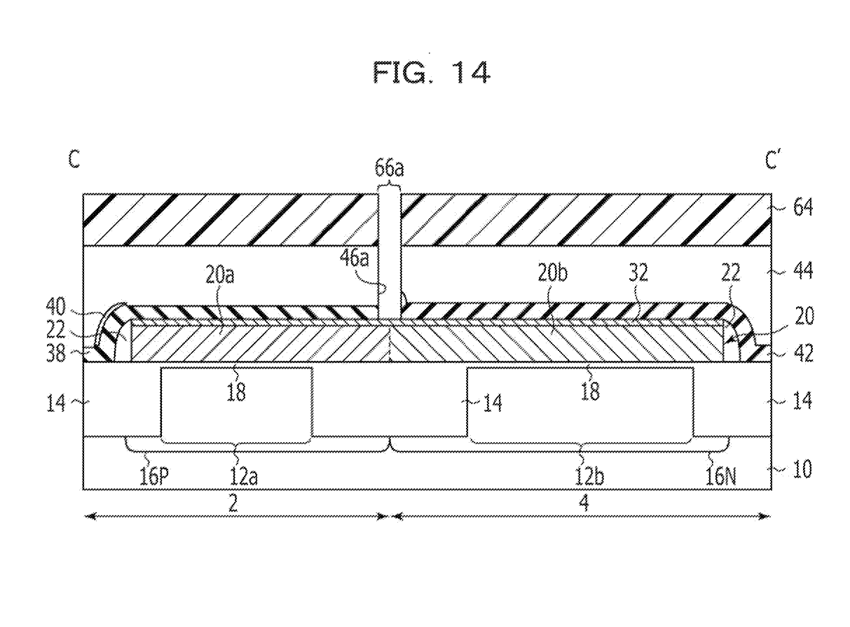

Next, the photoresist film 64 is formed by a spin coat method, for example (FIGS. 13 and 14).

Next, openings 66a to 66c are formed in the photoresist film 64 using a photolithographic technique. The opening 66a forms the contact hole 46a. The opening 66a is formed so that the center of the opening 66a is located above the broad portion 21 of the gate wiring 20 at the boundary between the NMOS transistor region 2 and the PMOS transistor region 4. The openings 66b and 66c form the contact holes 46b and 46c, respectively. Each of the openings 66b and 66c is formed in such a manner as to be located above the silicide layer 32.

Next, the interlayer insulation film 44 is etched using the photoresist film 64 as a mask. Since the interlayer insulation film 44 and the stress films 38 and 42 are different from each other in the etching characteristics, the stress films 38 and 42 are hardly etched. Thus, the contact holes 46a to 46c are formed in such a manner as to reach the stress films 38 and 42.

Next, the stress films 38 and 42 exposed in the contact holes 46a to 46c are etched using the photoresist film 64 as a mask.

Thus, the contact hole 46a is formed in the interlayer insulation film 44, the stress film 42, and the stress film 38 in such a manner as to reach the broad portion 21 of the gate wiring 20 at the boundary between the NMOS transistor region 2 and the PMOS transistor region 4. The contact hole 46a penetrates the interlayer insulation film 44, the stress film 42, and the stress film 38.

The contact hole 46b that reaches the silicide layer 32 on the source/drain diffusion layers of the NMOS transistor 34 is formed in the interlayer insulation film 44 and the stress film 38 in the NMOS transistor region 2. Moreover, in the interlayer insulation film 44 and the stress film 42 in the PMOS transistor region 4, the contact hole 46c that reaches the silicide layer 32 on the source/drain diffusion layers of the PMOS transistor 36 is formed.

The stress film 38 and the stress film 42 are a little different from each other in the etching characteristics. However, the difference in the etching rate between the stress film 38 and the stress film 42 is so small that it may be disregarded as compared with the difference in the etching rate between the etching stopper film 40 and the stress film 42. The difference in the etching rate between the stress film 38 and the stress film 42 is so small that it may be disregarded as compared with the difference in the etching rate between the etching stopper film 40 and the stress film 38. Even when the etching rate of the stress film 38 and the stress film 42 are a little different from each other, the formation of the contact hole 46a is not blocked and no special problems occur.

Thereafter, the photoresist film 64 is removed by ashing, for example.

Next, the barrier metal film 48 is formed on the entire surface by a sputtering method, for example. The barrier metal film 48 is formed by successively laminating a Ti film (not illustrated) and a TiN film (not illustrated), for example. The thickness of the Ti film is about 3 to 10 nm, for example. The thickness of the TiN film is about 3 to 10 nm, for example.

Next, a conductive film is formed on the entire surface by a CVD method, for example. The conductive film serves as the conductor plugs 50a to 50c. As the conductive film, a tungsten film is formed, for example. The thickness of the conductive film is about 50 to 400 nm, for example.

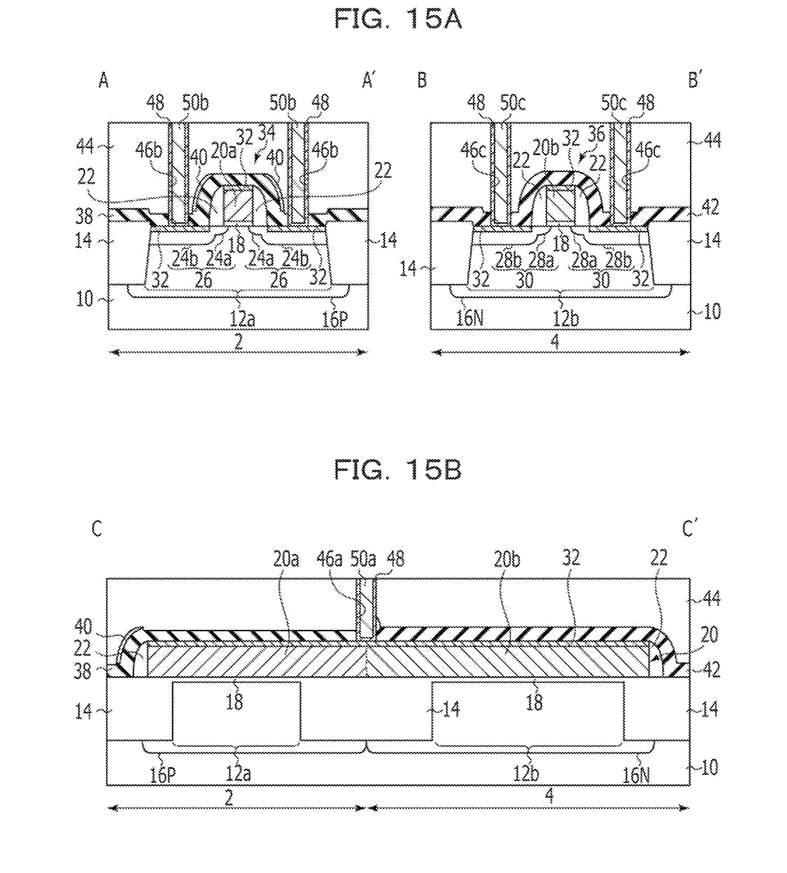

Next, the conductive film and the barrier metal film 48 are polished until the surface of the interlayer insulation film 44 is exposed by a CMP method, for example. Thus, the conductor plugs 50a to 50c are embedded in the contact holes 46a to 46c, at which the barrier metal film 48 is formed, respectively (FIGS. 15A and 15B). The conductor plug 50a is connected to the gate wiring 20 at the boundary between the NMOS transistor region 2 and the PMOS transistor region 4. The conductor plug 50b is connected to the silicide layer 32 on the source/drain diffusion layers of the NMOS transistor 34. The conductor plug 50c is connected to the silicide layer 32 on the source/drain diffusion layers of the PMOS transistor 36.

Thereafter, a wiring and the like (not illustrated) are formed.

Thus, the semiconductor device according to this embodiment is manufactured.

Thus, according to this embodiment, the etching stopper film 40 is selectively left on the portions covering the sidewall insulation films 22 of the stress film 38, and the etching stopper film 40 is removed in other portions. Therefore, according to this embodiment, the contact hole 46a in a favorable state may be formed without the etching being not blocked with the etching stopper film 40 during the formation of the contact hole 46a. Moreover, according to this embodiment, the portions covering the sidewall insulation films 22 of the stress film 38 are not etched, and thus a sufficient stress may be applied to the channel region of the transistor 34. Therefore, according to this embodiment, a reliable semiconductor device may be provided with a high manufacturing yield while achieving the improvement in the carrier mobility of a transistor.

The invention may be variously modified without being limited to the above-described embodiment.

For example, although the NMOS transistor 34 is formed in the region 2 and the PMOS transistor 36 is formed in the region 4 in the above-described embodiment, the PMOS transistor 36 may be formed in the region 2 and the NMOS transistor 34 may be formed in the region 4. In this case, it is preferable to form a compressive stress film as the stress film 38 and form a tensile stress film as the stress film 42.

Moreover, although the silicon nitride film is formed as the stress film 38 in the above-described embodiment, the stress film 38 is not limited to the silicon nitride film. A film capable of applying a stress to the channel region of the transistor formed in the region 2 may be formed as appropriate.

Moreover, although the silicon nitride film is formed as the stress film 42 in the above-described embodiment, the stress film 42 is not limited to the silicon nitride film. A film capable of applying a stress to the channel region of the transistor formed in the region 4 may be formed as appropriate.

Moreover, although the silicon oxide film is formed as the etching stopper film 40 in the above-described embodiment, the etching stopper film 40 is not limited to the silicon oxide film. A film different from the stress film 42 in the etching characteristics may be used as the etching stopper film 40 as appropriate.

Moreover, although the gate electrodes 20a and 20b are formed by introducing, as appropriate, a dopant into the gate wiring 20 formed with a polysilicon film in the above-described embodiment, the materials of the gate wiring 20 are not limited thereto. For example, the gate wiring 20 may be formed with a metal film.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A method for manufacturing a semiconductor device, comprising:
forming a first stress film covering a first transistor arranged in a first region and a second transistor arranged in a second region on a semiconductor substrate;
forming an etching stopper film, which possesses etching characteristics different from etching characteristics of the first stress film, on the first stress film;
etching the etching stopper film to selectively leave the etching stopper film at a portion covering a sidewall portion of the first stress film in the first region;
removing both the etching stopper film and the first stress film in the second region;
forming a second stress film, which possesses etching characteristics different from the etching characteristics of the etching stopper film, on the semiconductor substrate in such a manner as to cover the second transistor, the first stress film, and the etching stopper film; and
removing the second stress film in the first region.

2. The method for manufacturing a semiconductor device according to claim 1, further comprising
forming an insulating layer covering the first stress film, the etching stopper film, and the second stress film on the semiconductor substrate;
forming a contact hole that penetrates the insulating layer, the second stress film, and the first stress film in such a manner as to reach a gate wiring at the boundary between the first region and the second region; and
embedding a conductor plug in the contact hole.

3. The method for manufacturing a semiconductor device according to claim 1, wherein
the sidewall of the first stress film is a portion of the first stress film that covers a sidewall insulation film.

4. The method for manufacturing a semiconductor device according to claim 1, wherein
the etching of the etching stopper film is performed by anisotropic etching.

5. The method for manufacturing a semiconductor device according to claim 1, wherein
removing the second stress film includes etching the second stress film so that a part of the second stress film is overlapped with a part of the first stress film.

6. The method for manufacturing a semiconductor device according to claim 1, wherein
the first transistor is one of a PMOS transistor and an NMOS transistor; and
the second transistor is the other one of the PMOS transistor and the NMOS transistor.

7. The method for manufacturing a semiconductor device according to claim 1, wherein
the first stress film is one of a compressive stress film and a tensile stress film; and
the second stress film is the other one of the compressive stress film and the tensile stress film.

8. The method for manufacturing a semiconductor device according to claim 1, wherein
the first stress film is a silicon nitride film; and
the second stress film is another silicon nitride film.

9. The method for manufacturing a semiconductor device according to claim 1, wherein
the etching stopper film is a silicon oxide film.
